(19) United States
(12) Patent Application Publication
(10) Pub. No.: US 2015/0355282 A1
(43) Pub. Date: Dec. 10, 2015

(54) METHOD OF ESTIMATING REMAINING BATTERY ENERGY

(71) Applicants: HYUNDAI MOTOR COMPANY, Seoul (KR); Kia Motors Corporation, Seoul (KR)

(72) Inventors: Dong Gil HA, Changwon-si (KR); Woo Sung KIM, Suwon-si (KR)

(21) Appl. No.: 14/513,015

(22) Filed: Oct. 13, 2014

(30) Foreign Application Priority Data
Jun. 10, 2014 (KR) 10-2014-0069919

(51) Int. Cl. G01R 31/36

(52) U.S. Cl. CPC G01R 31/3606; G01R 31/3648; G01R 31/3662

(57) ABSTRACT

A method of estimating remaining energy of a battery Includes calculating a no-load energy of the battery. An estimated energy is calculated by reflecting predicted energy consumption due to an internal resistance and polarization into the calculated no-load energy. Remaining energy is calculated by calculating a correction value proportional to a difference between an estimated terminal voltage and a currently-measured terminal voltage and reflecting the correction value into the estimated energy.

### CROSS REFERENCE TO RELATED APPLICATION

The present application claims the benefit of priority to Korean Patent Application No. 10-2014-0069919, filed on Jun. 10, 2014, the entire contents of which is incorporated herein for all purposes by this reference.

### TECHNICAL FIELD

The present disclosure relates, in general, to a method of estimating remaining battery energy which can accurately and rapidly estimate the remaining energy of a high-voltage battery used in an environmentally friendly vehicle, such as a hybrid vehicle or an electric vehicle, and notify a user of the fuel efficiency of the vehicle or a distance that the vehicle can travel with the remaining battery energy.

### BACKGROUND

Environmentally friendly vehicles, such as hybrid vehicles, electric vehicles, and fuel cell vehicles, require a technology for estimating a distance that a vehicle can travel with a battery and notifying a driver of the estimated distance such that the battery can be charged at a suitable point of time. For this purpose, remaining energy estimation that can provide an accurate reading of the remaining battery energy is essential.

The value of the remaining battery energy varies according to usage conditions (e.g., state of charge (SOC), battery degradation level, electric current usage, and temperature changes) when the battery status appears to be unchanged from its initial state. In practice, some factors are impossible to estimate without information about driver's tendencies and habits or traffic/geographic information such as traffic conditions related to an area where the vehicle is traveling.

In the related art, many methods have been introduced in order to estimate the remaining energy of a battery. However, these methods require an enormous number of tests at different levels of electric current under various temperature/SOC conditions. In practice, it is impossible to perform all of the tests.

For example, a battery operates at a temperature ranging from −30° C. to 50° C., a SOC ranges from 5% to 90%, and an electric current ranges from −300 A to 300 A. The number of tests to be conducted is 567 (when the tests are performed at every 10° C., 10% SOC, and 100 A), and thus, the entire number of required tests is too high.

Even if such an enormous number of tests were to be performed, it would be impossible to estimate the actual travel conditions of a vehicle, and thus, the remaining battery energy may be inaccurately estimated.

The information disclosed in the Background of the Invention section is only for the enhancement of understanding of the background of the invention, and should not be taken as an acknowledgment or as any form of suggestion that this information forms a prior art that would already be known to a person skilled in the art.

### SUMMARY

The present disclosure has been made keeping in mind the above problems occurring in the related art, and the present disclosure proposes a method of estimating remaining battery energy which can accurately and rapidly estimate the remaining energy of a high-voltage battery used in an environmentally friendly vehicle, such as a hybrid vehicle or an electric vehicle, and notify a user of the fuel efficiency of the vehicle and/or a distance that the vehicle can travel with the remaining battery energy.

According to an exemplary embodiment of the present invention, a method of estimating remaining energy of a battery includes calculating a no-load energy of the battery. An estimated energy is calculated by reflecting a predicted energy consumption due to internal resistance and polarization into the calculated no-load energy. Remaining energy is calculated by calculating a correction value proportional to a difference between an estimated terminal voltage and a currently-measured terminal voltage and by reflecting the correction value into the estimated energy.

In the step of calculating the no-load energy, the no-load energy of the battery may be calculated based on map data that has a state of charge (SOC) and a temperature of the battery as inputs and the no-load energy as an output.

In the step of calculating the estimated energy, the predicted energy consumption due to an internal resistance may be calculated by multiplying an average internal resistance, a predicted electric current, and a battery capacity.

The average internal resistance may be deduced from a function depending on predicted temperatures, and the battery capacity may be deduced from a function depending on SOCs.

In the step of calculating the estimated energy, the predicted energy consumption due to the polarization may be calculated by multiplying an average polarization voltage and a battery capacity.

The average polarization voltage may be deduced from a function depending on predicted temperatures, and the battery capacity may be deduced from a function depending on SOCs.

In the step of calculating the remaining energy, the correction value may be calculated by multiplying the difference between the estimated terminal voltage and the currently-measured terminal voltage by a battery capacity.

The estimated terminal voltage may be deduced by adding up an electromotive force, a value produced by multiplying the internal resistance and an electric current, and a polarization voltage.

The electromotive force may be deduced from a function depending on SOCs and temperatures.

The internal resistance may be deduced from a function depending on SOCs and predicted temperatures.

The polarization voltage may be deduced from a function depending on states of charge, temperatures, and electric currents.

According to another aspect of the present invention, a method of estimating remaining energy of a battery includes calculating no-load energy of a battery. An estimated energy is calculated by reflecting estimated energy consumption due to an internal resistance and polarization into the calculated no-load energy. A correction value proportional to a difference between an estimated terminal voltage and a currently-measured terminal voltage is calculated. The correction value is reflected into the estimated energy.

According to a further aspect of the present invention, a method of estimating remaining energy of a battery by the following formula:

Eᵣₑₘₐᵢₙ=Energy_{NL}(soc,T)+[R_{iavg}(T)*I+V_{pavg}(T)K(soc,t)*(Vₜ−\hat{V}ₜ)]*cap(SOC),

where Energy_{NL}(soc,T) indicates a data map that has a present status of charge and an estimated temperature as inputs and a no-load energy as an output, R_{iavg}(T) indicates an average internal resistance that has the estimated temperature as an input, I indicates an average electric current, V_{pavg}(T) indicates an average polarization voltage that has the estimated temperature as an input, K(soc,t) indicates a correction gain that has the present SOC and the present temperature as an input, Vₜ indicates a present terminal voltage, \hat{V}ₜ indicates an estimated terminal voltage, and Cap(SOC) indicates a battery capacity that has the estimated SOC as an input.

According to the method of estimating remaining battery energy as described above, it is possible to accurately and rapidly estimate the remaining energy of a high-voltage battery used in an environmentally friendly vehicle, such as a hybrid vehicle or an electric vehicle, and notify a user of the fuel efficiency of the vehicle and/or a distance that the vehicle can travel with the remaining battery energy.

Since the remaining energy is estimated by predicting the usage conditions of the battery which change in real time and is corrected through comparison with the present values, accuracy is improved. In addition, the battery model precludes an enormous number of tests, thereby reducing the development cost and time.

In addition, it is possible to improve accuracy in the estimation of the distance that a vehicle can travel with the remaining battery energy by referring to the estimated remaining energy. The improved accuracy in the estimation of the distance that a vehicle can travel with the remaining battery energy can also improve the commercial value of environmentally friendly vehicles.

### BRIEF DESCRIPTION OF THE DRAWINGS

The above and other objects, features and advantages of the present disclosure will be more clearly understood from the following detailed description when taken in conjunction with the accompanying drawings.

FIG. 1 is a block diagram showing a method of estimating remaining battery energy according to an exemplary embodiment of the present invention.

FIG. 2 is a graph showing discharge energy of a battery according to temperature and state of charge (SOC).

FIG. 3 is a graph showing an internal resistance of the battery depending on the temperature and the SOC.

### DETAILED DESCRIPTION

Reference will now be made in greater detail to an exemplary embodiment of the present invention, an example of which is illustrated in the accompanying drawings. Wherever possible, the same reference numerals will be used throughout the drawings and the description to refer to the same or like parts.

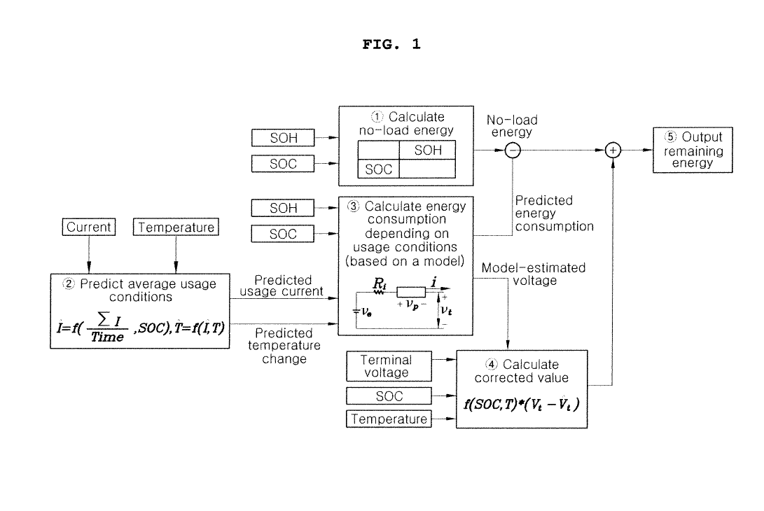

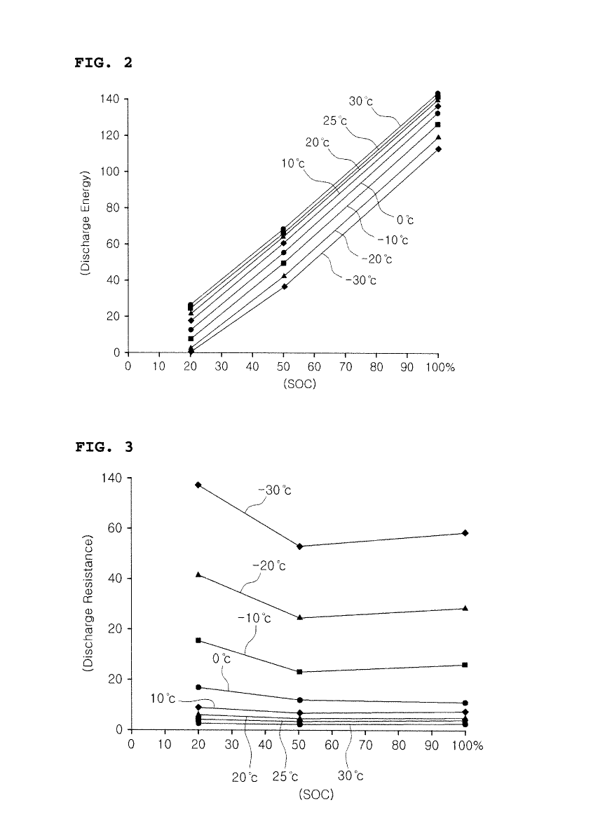

FIG. 1 is a block diagram showing a method of estimating remaining battery energy according to an exemplary embodiment of the present invention. FIG. 2 is a graph showing a discharge energy of a battery according to temperature and SOC. FIG. 3 is a graph showing an internal resistance of the battery depending on the temperature and the SOC.

FIG. 1 is a block diagram showing a method of estimating remaining battery energy according to an exemplary embodiment of the present invention. The method of estimating remaining battery energy according to an embodiment includes a no-load energy calculation step of calculating a no-load energy of a battery. An estimated energy calculation step calculates estimated energy by reflecting predicted energy consumption due to internal resistance and polarization back into the calculated no-load energy. A remaining energy calculation step calculates remaining energy by calculating a correction value proportional to the difference between an estimated terminal voltage and a currently-measured terminal voltage and reflecting the correction value back into the estimated energy.

The method according to the embodiment of the invention includes the no-load energy calculation step of referring to an SOC-based no-load discharge energy table extracted by a low-current discharge test and based on a battery model (S1). An average usage conditions prediction step determines average predicted usage conditions by receiving electric current and temperature data of the battery while a vehicle travels (S2). A predicted energy consumption calculation step calculates predicted energy consumption depending on the usage conditions based on the predicted usage conditions, which are determined at step S2, as well as the battery model (S3). A correction calculation step corrects remaining energy by receiving a battery terminal voltage, compares the received battery terminal voltage with a model voltage estimated at step S3, and then reflects the compared difference depending on the present temperature and SOC back into the remaining energy (S4). A remaining energy output step outputs corrected remaining energy (S5).

Specifically, at the no-load energy calculation step, it is possible to calculate the no-load energy of the battery based on map data that has the SOC and the temperature of the battery as inputs and the no-load energy as an output.

FIG. 2 is a graph showing a discharge energy of a battery according to temperature and SOC. In FIG. 2, the horizontal axis indicates the SOC, and the vertical axis indicates the discharge energy according to 1 C-rate discharge test. Referring to the inclination of the graph, more particularly, to a specific temperature, it is apparent that the discharge energy linearly varies depending on the SOC. However, the inclination of the discharge energy is not linear with respect to the temperature in terms of specific SOC. Therefore, the no-load energy of the battery cannot be calculated based on a simple formula but can be deduced based on a data map that has the SOC and the temperature as inputs. The no-load energy data map can be prepared by multiplying an open circuit voltage (OCV) at a specific SOC and temperature by 1 C-rate value and then integrating the multiplied value. The input SOC is the present temperature of the battery, and the temperature is a predicted temperature. The predicted temperature can be the present temperature of the battery, can be used by averaging accumulated temperatures of the battery, or can be deduced from the map data depending on the status of the vehicle.

The estimated energy calculation step calculates the estimated energy by reflecting the predicted energy consumption due to the internal resistance and polarization to the calculated no-load energy. Specifically, the predicted energy consumption due to the internal resistance can be produced by multiplying an average internal resistance, a predicted electric current and battery capacity. The average internal resistance can be deduced from a function depending on the predicted temperature, and the battery capacity can be deduced from a function depending on the SOC. Each of the functions can be composed of a data map or a simple formula.

FIG. 3 is a graph showing the internal resistance of the battery depending on the temperature and SOC. In FIG. 3, the horizontal axis indicates the SOC, and the vertical axis indicates discharge resistance. Referring to the inclination of the graph, the discharge resistance varies according to the SOC and is non-linearly proportional to the temperature. Therefore, the average internal resistance can be an average test value selected depending on the temperature.

In addition, the predicted energy consumption due to polarization can be calculated by multiplying an average polarization voltage and the battery capacity. The average polarization voltage can be deduced from a function depending on the predicted temperature, and the battery capacity can be deduced from a function depending on the SOC.

The predicted energy consumption is deduced by Formula 1 below:

∫ₜ_{ₛ}^{t}^{ₑ}Rᵢ(soc,T)*I²dt+∫ₜ_{ₛ}^{t}^{ₑ}Vₚ(soc,T,I)*Idt=R_{iavg}(T)*Cap(SOC)*I+V_{pavg}(T)*Cap(SOC), [Formula 1]

where tₛ indicates a point of time of use, tₑ indicates a point of time when energy is 0, Rᵢ indicates an inter: resistance, soc indicates a present SOC, SOC indicates a an predicted SOC. T indicates a predicted temperature, R_{iavg} indicates an average internal resistance from tₛ to tₑ, V_{pavg} indicates an average polarization voltage from tₛ to tₑ, Cap(SOC) indicates a battery capacity, and I indicates a predicted electric current.

The predicted values such as the predicted temperature and the predicted electric current can be predicted as future values depending on the past traveling statuses based upon a data map or a simple formula, as mentioned above, or can be selected according to the present status of the vehicle.

Afterwards, the remaining energy calculation step calculates remaining energy by calculating a correction value proportional to the difference between an estimated terminal voltage and a currently-measured terminal voltage and by reflecting the correction value back into the estimated energy.

In the remaining energy calculation step, the correction value can be produced by multiplying the difference between the estimated terminal voltage and the currently-measured terminal voltage by the battery capacity. The estimated terminal voltage can be deduced by adding up an electromotive force, a value produced by multiplying the internal resistance and the electric current, and the polarization voltage.

The electromotive force can be deduced from a function depending on the SOC and the temperature. In addition, the internal resistance can be deduced from a function depending on the SOC and the estimated temperature. In addition, the polarization voltage can be deduced from a function depending on the temperature and the electric current.

In brief, the method of estimating remaining battery energy according to this embodiment calculates the remaining energy by calculating the no-load energy of the battery, calculating the estimated energy by reflecting the predicted energy consumption due to the internal resistance and polarization back into the calculated no-load energy, calculating the correction value proportional to the difference between the estimated terminal voltage and the currently-measured terminal voltage, and reflecting the correction value back into the estimated energy.

The estimated value of the terminal voltage can be deduced from Formula 2 below:

\hat{V}ₜ=V_{emf}(soc,t)+Rᵢ(soc,T)*i+Vₚ(soc,t,i), [Formula 2]

where \hat{V}ₜ indicates an estimated voltage, i indicates a current sensor value, t indicates a battery temperature sensor value, V_{emf} indicates an electromotive force, Rᵢ indicates an internal resistance, and Vₚ indicates a polarization voltage.

To conclude, the method of estimating remaining battery energy according to this embodiment can be expressed by Formula 3 below:

Eᵣₑₘₐᵢₙ=Energy_{NL}(soc,T)+[R_{iavg}(T)*I+V_{pavg}(T)+K(soc,t)*(Vₜ−\hat{V}ₜ)]*Cap(SOC), [Formula 3]

where Energy_{NL}(soc,T) indicates a data map that has a present SOC and an estimated temperature as inputs and no-load energy as an output, R_{iavg}(T) indicates an average internal resistance that has the estimated temperature as an input, I indicates an average electric current, V_{pavg}(T) indicates an average polarization voltage that has the estimated temperature as an input, K(soc,t) indicates a correction gain that has the present SOC and the present temperature as inputs, Vₜ indicates a present terminal voltage, \hat{V}ₜ indicates an estimated terminal voltage, and Cap(SOC) indicates a battery capacity that has the estimated SOC as an input.

According to Formula 3 above, the no-load energy is deduced from the data map by inputting the present SOC and the predicted temperature into the data map. The influence of the internal resistance and the polarization voltage is deduced depending on the predicted temperature and electric current, and then is inputted back into the remaining energy calculation. In particular, the difference between the present terminal voltage and the predicted terminal voltage is reflected back into the formula as a correction value. Accordingly, a relatively accurate value of the remaining battery power can be advantageously estimated.

According to the method of estimating remaining battery energy as described above, it is possible to accurately and rapidly estimate the remaining energy of a high-voltage battery used in an environmentally friendly vehicle, such as a hybrid vehicle or an electric vehicle, and notify a user of the fuel efficiency of the vehicle and/or a distance that the vehicle can travel with the remaining battery energy.

Since the remaining energy is estimated by predicting the usage conditions of the battery which change in real time and is corrected through comparison with the present values, accuracy is improved. In addition, the battery model precludes an enormous number of tests, thereby reducing the development time and cost.

In addition, it is possible to improve accuracy in the estimation of the distance that a vehicle can travel with the remaining battery energy by referring to the estimated remaining energy. The improved accuracy in the estimation of the distance that a vehicle can travel with the remaining battery energy can also improve the commercial value of environmentally friendly vehicles.

Although the exemplary embodiments of the present invention have been described for illustrative purposes, those skilled in the art will appreciate that various modifications, additions and substitutions are possible, without departing from the scope and spirit of the present invention as disclosed in the accompanying claims.

What is claimed is:

1. A method of estimating remaining energy of a battery, comprising steps of:
calculating a no-load energy of the battery;
calculating an estimated energy by reflecting a predicted energy consumption due to an internal resistance and polarization into the calculated no-load energy; and
calculating the remaining energy by calculating a correction value proportional to a difference between an estimated terminal voltage and a currently-measured terminal voltage and reflecting the correction value into the estimated energy.

2. The method according to claim 1, wherein the step of calculating the no-load energy comprises calculating the no-load energy of the battery based on map data that has a state of charge (SOC) and a temperature of the battery as inputs and the no-load energy as an output.

3. The method according to claim 1, wherein the step of calculating the estimated energy comprises calculating the predicted energy consumption due to the internal resistance by multiplying an average internal resistance, a predicted electric current, and a battery capacity.

4. The method according to claim 3, wherein the average internal resistance is deduced from a function depending on predicted temperatures, and the battery capacity is deduced from a function depending on SOCs.

5. The method according to claim 1, wherein the step of calculating the estimated energy comprises calculating the predicted energy consumption due to the polarization by multiplying an average polarization voltage and a battery capacity.

6. The method according to claim 5, wherein the average polarization voltage is deduced from a function depending on predicted temperatures, and the battery capacity is deduced from a function depending on SOCs.

7. The method according to claim 1, wherein the step of calculating the remaining energy comprises calculating the correction value by multiplying the difference between the estimated terminal voltage and the currently-measured terminal voltage by a battery capacity.

8. The method according to claim 7, wherein the estimated terminal voltage is deduced by adding up an electromotive force, a value produced by multiplying the internal resistance and an electric current, and a polarization voltage.

9. The method according to claim 8, wherein the electromotive force is deduced from a function depending on SOCs and temperatures.

10. The method according to claim 8, wherein the internal resistance is deduced from a function depending on the SOCs and predicted temperatures.

11. The method according to claim 8, wherein the polarization voltage is deduced from a function depending on SOCs, temperatures, and electric currents.

12. A method of estimating remaining energy of a battery comprising steps of:
calculating a no-load energy of the battery;
calculating an estimated energy by reflecting an estimated energy consumption due to an internal resistance and polarization into the calculated no-load energy;
calculating a correction value proportional to a difference between an estimated terminal voltage and a currently-measured terminal voltage; and
reflecting the correction value into the estimated energy.

13. A method of estimating remaining energy of a battery by the following formula:
Eᵣₑₘₐᵢₙ=Energy_{NL}(soc,T)+[R_{iavg}(T)*I+V_{pavg}(T)+K(soc,t)*(Vₜ−\hat{V}ₜ)]*Cap(SOC),
where Energy_{NL}(soc,T) indicates a data map that has a present status of charge and an estimated temperature as inputs and a no-load energy as an output, R_{iavg}(T) indicates an average internal resistance that has the estimated temperature as an input, I indicates an average electric current, V_{pavg}(T) indicates an average polarization voltage that has the estimated temperature as an input, K(soc,t) indicates a correction gain that has a present SOC and a present temperature as an input, Vₜ indicates a present terminal voltage, \hat{V}ₜ indicates an estimated terminal voltage, and Cap(SOC) indicates a battery capacity that has an estimated SOC as an input.

14. The method according to claim 4, wherein the predicted temperatures are a present temperature of the battery, which are obtained by averaging accumulated temperatures of the battery or deduced from map data.

15. The method according to claim 6, wherein the predicted temperatures are a present temperature of the battery, which are used by averaging accumulated temperatures of the battery or deduced from map data.

16. The method according to claim 10, wherein the predicted temperatures are a present temperature of the battery, which are used by averaging accumulated temperatures of the battery or deduced from map data.

17. The method according to claim 13, wherein the predicted energy consumption is deduced by the following formula:
∫ₜ_{ₛ}^{t}^{ₑ}Rᵢ(soc,T)*I²dt+∫ₜ_{ₛ}^{t}^{ₑ}Vₚ(soc,T,I)*Idt=R_{iavg}(T)*Cap(SOC)*I+V_{pavg}(T)*Cap(SOC),
where tₛ indicates a point of time of use, tₑ indicates a point of time when energy is 0, Rᵢ indicates an internal resistance, soc indicates the present SOC, SOC indicates the predicted SOC, T indicates a predicted temperature, R_{iavg}(T) indicates the average internal resistance from ts to te, V_{pavg}(T) indicates the average polarization voltage from tₛ to tₑ, Cap(SOC) indicates the battery capacity, and I indicates a predicted electric current.

18. The method according to claim 13, wherein the estimated terminal voltage is deduced from the following formula:
\hat{V}ₜ=V_{emf}(soc,t)+Rᵢ(soc,T)*i+Vₚ(soc,t,i),
where \hat{V}ₜ indicates an estimated voltage, i indicates a current sensor value, t indicates a battery temperature sensor value, V_{emf} indicates an electromotive force, Rᵢ indicates an internal resistance, and Vₚ indicates a polarization voltage.
